(19) United States
(12) Patent Application Publication
(10) Pub. No.: US 2006/0160253 A1
(43) Pub. Date: Jul. 20, 2006

(54) Method and apparatus for wafer temperature regulation

(76) Inventors: Bong-Kil Kim, Osan-si (KR); Dae-Ho Go, Osan-si (KR); Yun-Jung Moon, Hwaseong-si (KR)

Correspondence Address: HARNESS, DICKEY & PIERCE, P.L.C., P.O. BOX 8910, RESTON, VA, 20195, US

(21) Appl. No.: 11/332,315

(22) Filed: Jan. 17, 2006

(30) Foreign Application Priority Data
Jan. 20, 2005 (KR) 10-2005-0005485

(51) Int. Cl. H01L 21/66; H01L 21/02

(52) U.S. Cl. 438/5; 438/14

(57) ABSTRACT

A method and apparatus for regulating the temperature a wafer is provided. The apparatus may include a temperature controlling unit provided within the chamber and regulating the temperature of the wafer; a wafer support pin for adjusting the position of the wafer with respect to the temperature controlling unit; and/or a positioning assembly for adjusting the wafer support pin by which the position of the wafer is controlled. The temperature of a wafer baked at a high temperature may be regulated by performing a series of temperature controlling operation in order to reduce the possibility of fracturing the wafer due to a change in temperature.

### PRIORITY STATEMENT

This application claims the benefit of Korean Patent Application No. 10-2005-0005485, filed on Jan. 20, 2005, in the Korean Intellectual Property Office, the disclosure of which is incorporated herein in its entirety by reference.

### BACKGROUND

1. Field of the Invention

The example embodiments of present invention relate to a method and apparatus for regulating the temperature of a wafer, and more particularly, to a method and apparatus for regulating the temperature a wafer heated during a photolithography process.

2. Description of the Related Art

In general, the formation of a circuit pattern on a wafer may be necessary in the production of a semiconductor apparatus. A photolithography process is commonly used during the production of a semiconductor apparatus.

In a photolithography process, a surface of a wafer may be coated with a photoresist, which chemical properties that have been altered due to light. A reticle with a circuit pattern may be placed on the wafer. A light, of a particular wavelength, may be radiated on the reticle, so that the circuit pattern of the reticle is copied onto the photoresist coated on the surface of the wafer. The wafer with the circuit pattern, may be developed, so that the circuit pattern is formed on the wafer.

In order to form a circuit pattern according to a photolithography process, it may be necessary to perform multiple wafer baking operations.

For example, prior to coating the photoresist on the wafer, an anti-reflective coating (ARC) layer may be coated on top of a lower coating layer of the wafer in order to substantially block light from being reflected off of the lower coating layer. The wafer may be loaded on an apparatus for performing the photolithography process and undergo a first baking operation. After coating the photoresist on the wafer, a second baking operation may be performed in order to harden the coated photoresist layer on a surface of the wafer. After the photoresist layer may be exposed to a light source, a third operation is performed in order to heat the exposed photoresist layer and harden the pattern. After the photoresist layer is developed on the wafer, a fourth baking operation may be performed to secure the pattern formed during development and remove moisture.

After the multiple baking operations, a cooling operation may be performed for rapidly cooling the baked wafer to a desired temperature.

According to conventional methods and apparatuses for cooling a wafer, the baked wafer is loaded onto a cooling plate using an air cylinder, or similar device, capable of movement in a vertical direction. The baked wafer then is positioned directly on the upper surface of the cooling plate, and subsequently undergoes a rapid drop in temperature before being transferred to the next process.

Accordingly, the wafer may constrict and/or fracture as a result of the temperature difference between the wafer and the cooling plate. In particular, because the wafer is baked at a relatively high temperature, e.g. approximately 225° C., during the first baking operation of a conventional method, and then rapidly cooled to a relatively low temperature, e.g. approximately 23° C., the wafer may constrict and/or fracture due to the temperature difference, e.g., between 225° C. and 23° C.

### SUMMARY

Example embodiments of the present invention provide a method and apparatus for regulating a temperature of a wafer, undergoing a change in temperature, while reducing, or preventing, the wafer from constricting and/or fracturing.

Example embodiments of the present invention also provide a method and apparatus for regulating the temperature of a wafer, baked one or more times at a relatively high temperature and undergoing a change in temperature, while reducing, or preventing, the wafer from constricting and/or fracturing.

According to another example embodiment of the present invention, there is provided a temperature regulating apparatus that may include a chamber; a temperature controlling unit provided within the chamber for providing a source of radiation; a wafer support pin for supporting the wafer; and/or a positioning assembly for adjusting the position of the wafer support pin.

According to an example embodiment of the present invention, the temperature controlling unit may include a thermoelectric module. The chamber may include a plate on which the wafer may be positioned. The temperature controlling unit may be provided within the plate. The plate may be formed of a thermally conductive material. The wafer support pin may move in a direction substantially perpendicular to a surface of the plate.

The positioning assembly may further include a driving motor; a screw unit, coupled to the driving motor and wafer support pin, for adjusting the position of the wafer support pin according to a rotation of the driving motor; and/or a controller, which may be electrically connected to the driving motor, for controlling a rotation direction and a rotation angle of the driving motor.

In another example embodiment of the present invention, the driving motor may include a stepping motor rotated at an angle that may rotate based on a corresponding input pulse value.

In another example embodiment, the positioning assembly may further include a temperature sensor for measuring a wafer temperature, and a controller. The controller may control the rotation direction and the angle of the driving motor as a wafer temperature is detected by the temperature sensor and relayed back to the controller.

In another example embodiment, the temperature sensor may be placed on the wafer support pin. Furthermore, the temperature sensor may be provided near the portion of the wafer support pin in contact with the wafer.

According to another example embodiment, the screw unit may further include a rotation shaft disposed along a direction of movement of the wafer support pin; a nut member coupled to the rotation shaft, which may be adjusted as the rotation shaft rotates; and wherein the wafer support pin may be coupled to the nut member.

In addition, the position assembly may further include a driving motor; a driving pulley coupled to the driving motor; a follower pulley spaced at a height toward a direction of movement of the wafer support pin; a timing belt, coupled to the driving pulley and follower pulley, for being rotated as the driving motor rotates; a joining member coupled to the timing belt and the wafer support pin; and/or a controller, which may be electrically connected to the driving motor, for controlling the rotation direction and angle of the driving motor.

In addition, the positioning assembly may further include a driving motor; a driving gear coupled to the driving motor; a follower gear located in the direction of the wafer support pin; a chain, coupled to the driving gear and follower gear, which rotates as the driving motor rotates; a joining member coupled to the chain and the wafer support pin; and/or a controller, electrically connected to the driving motor, for controlling the rotation direction and angle of the driving motor.

According to another example embodiment of the present invention, there is provided a method for regulating the temperature of a wafer that may include providing a temperature regulating apparatus that may include a chamber, a temperature controlling unit provided within the chamber and under a plate, a wafer support pin for adjusting the position of the wafer relative to the surface of the plate, and/or a positioning assembly for adjusting the position of the wafer support pin, and thereby the wafer; regulating the temperature of the wafer by adjusting the position of the loaded wafer a distance from the surface of a plate using the positioning assembly when the wafer is loaded on the surface of the wafer support pin; and further regulating the temperature of the wafer by adjusting the wafer to be in substantially direct or direct contact with the plate using the positioning assembly.

In an example embodiment of the present invention, a distance of the wafer, positioned on the wafer support pin, to the surface of the plate, during the initial position adjustment of the wafer may be to approximately 1 to 10 mm.

In an example embodiment, an amount of time to regulate the temperature of the wafer, during the initial position adjustment of the wafer, may be approximately 3 to 10 seconds.

In an example embodiment, the temperature regulation, performed during the initial position adjustment of the wafer, may be performed by thermal radiation from the temperature controlling unit.

In an example embodiment, the temperature regulation, performed during the subsequent position adjustment of the wafer, may be performed by thermal conduction and thermal radiation from the temperature controlling unit. Furthermore, the positioning assembly may include a temperature sensor for measuring the wafer temperature.

In an example embodiment, the subsequent position adjustment of the wafer may be performed when the temperature of the wafer, during the initial position adjustment of the wafer, reaches a temperature of approximately 90 to 120° C.

In another example embodiment, the temperature sensor may be included near the portion of the wafer support pin in substantially direct, or direct, contact with the wafer.

### BRIEF DESCRIPTION OF THE DRAWINGS

The above and other features of example embodiments of the present invention will be readily understood with reference to the following detailed description provided in conjunction with the accompanying drawings, wherein the same reference numerals designate corresponding structural elements, and in which:

FIG. 1 is a view illustrating an apparatus for regulating the temperature of a wafer according to an example, non-limiting embodiment of the present invention;

FIGS. 2 and 3 are views illustrating the adjustment of a wafer using the apparatus for regulating the temperature of a wafer shown in FIG. 1 according to an example, non-limiting embodiment of the present invention;

FIG. 4 is a block diagram of a method for regulating the temperature of a wafer according to a non-limiting, example embodiment of the present invention;

FIG. 5 is a view of an apparatus for regulating the temperature of a wafer illustrating a screw unit as the positioning assembly according to a non-limiting, example embodiment of the present invention;

FIG. 6 is a view of an apparatus for regulating the temperature of a wafer illustrating a pulley system as the positioning assembly according to a non-limiting, example embodiment of the present invention; and

FIG. 7 is a view of an apparatus for regulating the temperature of a wafer illustrating a gear system as the positioning assembly according to a non-limiting, example embodiment of the present invention.

### DETAILED DESCRIPTION EXAMPLE EMBODIMENTS OF THE INVENTION

Hereinafter, a method and apparatus for regulating the temperature of a wafer according to example, non-limiting embodiments of the present invention will be described below in detail with reference to the accompanying drawings. Like reference numerals in the drawings denote like elements therefore descriptions will not be repeated.

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

Spatially relative terms, such as “beneath”, “below”, “lower”, “above”, “upper” and the like, may be used herein for ease of description to describe one element or a feature's relationship to another element or feature as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the operations noted may occur out of the order noted in the FIGS. For example, two FIGS. shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments of the present invention belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to the example embodiments described. In the figures, if a layer is formed on another layer or a substrate, it means that the layer is directly formed on another layer or a substrate, or that a third layer is interposed therebetween. In the following description, the same reference numerals denote the same elements.

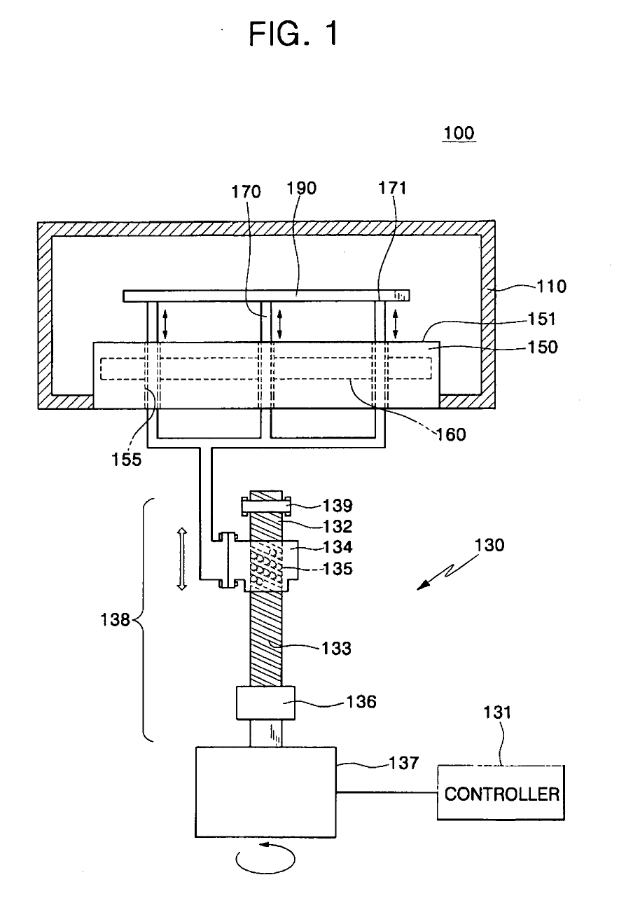

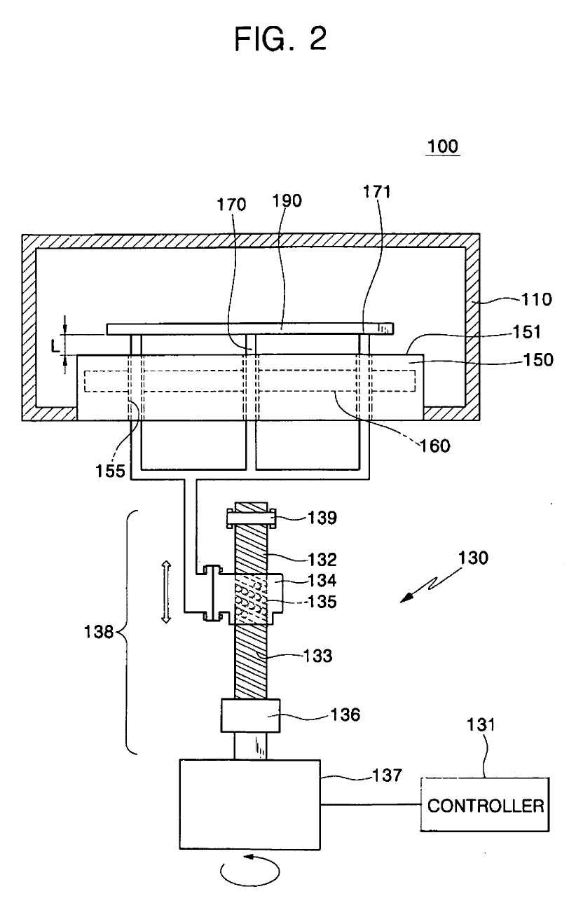

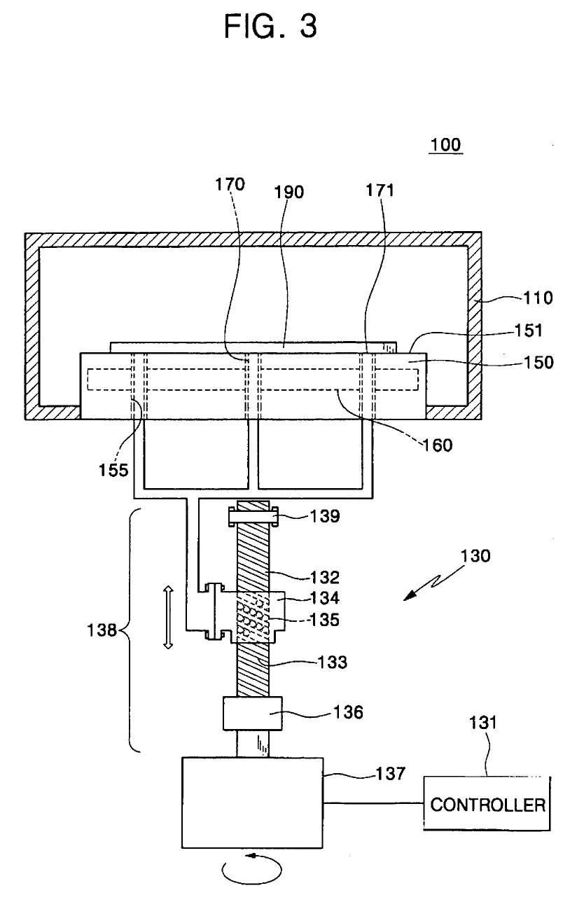

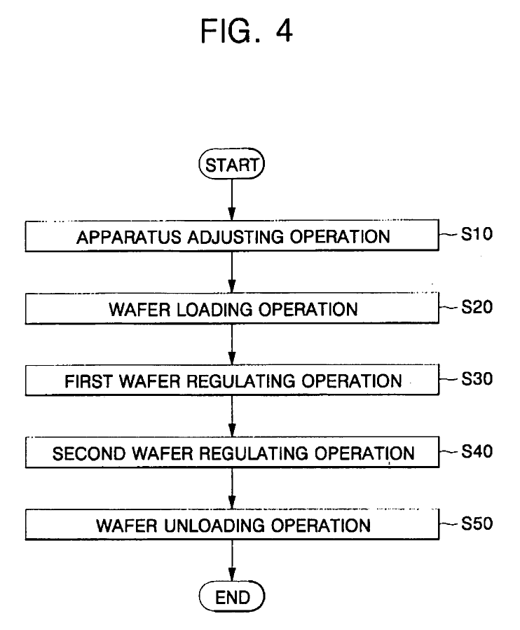

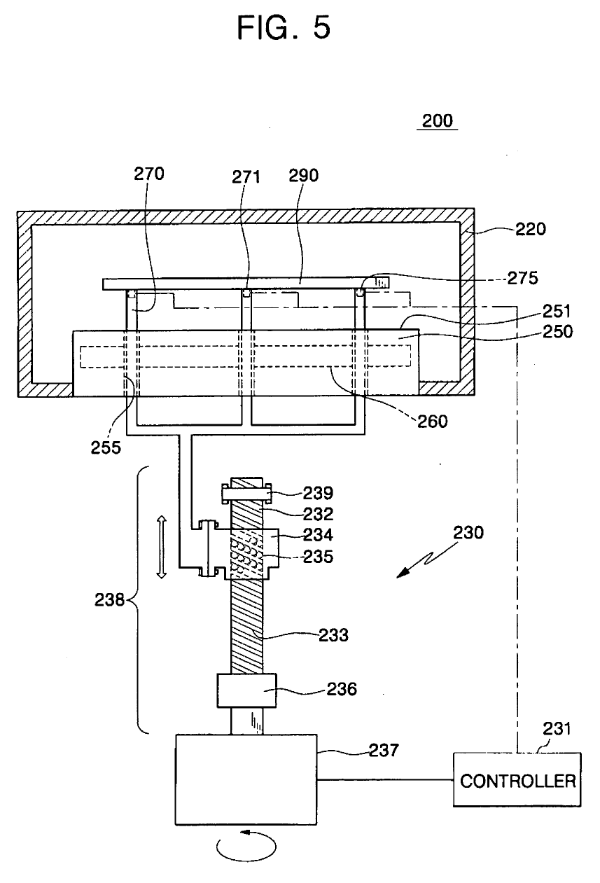

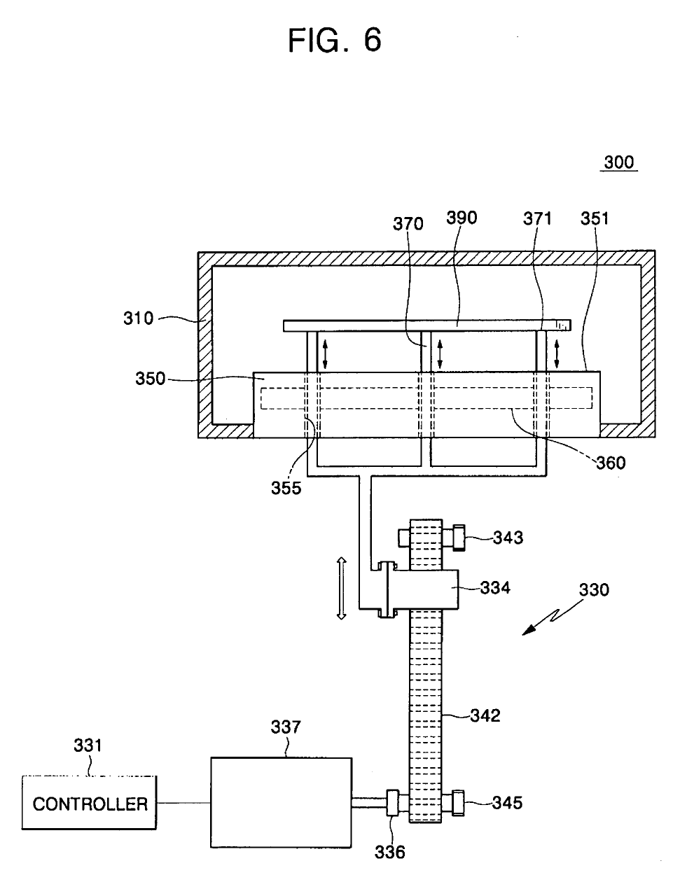

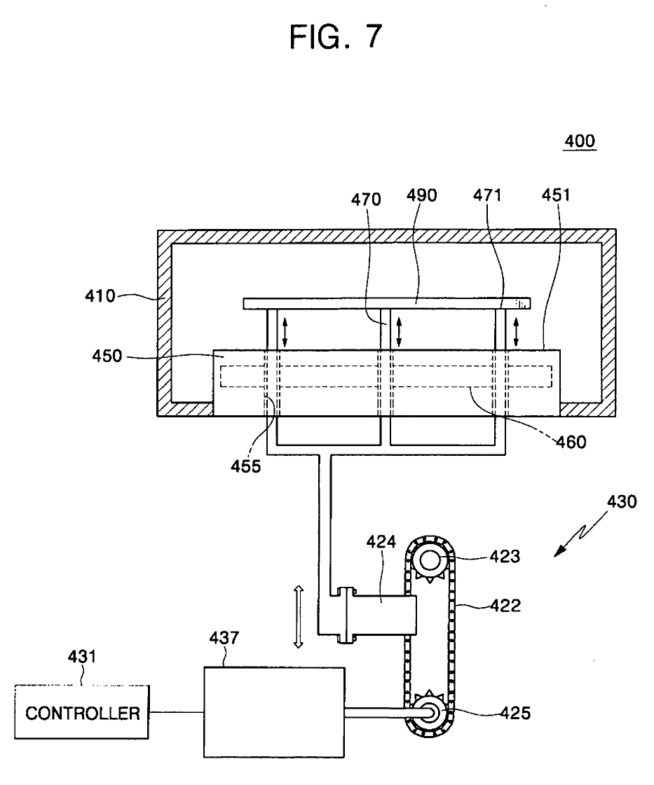

FIG. 1 is a view of an apparatus for regulating the temperature of a wafer according to an example embodiment of the present invention. FIGS. 2 and 3 are views illustrating the adjustment of a wafer using the apparatus for regulating the temperature of a wafer shown in FIG. 1. FIG. 4 is a block diagram of a method for regulating the temperature of a wafer according to an example embodiment of the present invention. FIG. 5 is a view of an apparatus for regulating the temperature of a wafer illustrating a screw unit as a positioning assembly according to another example embodiment of the present invention. FIG. 6 is a view of an apparatus for regulating the temperature of a wafer illustrating a pulley system as the positioning assembly according to yet another example embodiment of the present invention. FIG. 7 is a view of an apparatus for regulating the temperature of a wafer according to another example embodiment of the present invention.

Referring to FIGS. 1 to 3, an example embodiment of the present invention will be described. A temperature regulation apparatus 100 may include a chamber 110, a plate 150, a wafer support pin 170, a wafer 190 and/or a positioning assembly 130. The plate 150 may be located in the chamber 110. The wafer support pin 170, for supporting a wafer 190, may be capable of penetrating the plate 150 in any direction (e.g., up, down, diagonal, left, right, etc.) substantially parallel to a surface 151 of the plate 150. The positioning assembly 130 may adjust the wafer support pin 170 in order to control the position of the wafer 190.

The chamber 110 may be constructed in a shape having a cavity in its center, so that it may provide a hermetically sealed space. An opening part (not shown) may be provided on one side of the chamber 110 so that the wafer 190 may be loaded to or unloaded from the chamber 110. An opening and closing door (not shown), which may open or close the opening part when the wafer 190 is loaded or unloaded, may be provided in the opening part. The hermetic conditions may be maintained by a vacuum located in the chamber or in a transfer box connected to the chamber. Alternative configurations, e.g., a drying train filled with molecular sieves, to maintain a substantially airtight, moisture-free environment within the chamber are to be appreciated by one skilled in the art.

The plate 150 may be constructed in a cylindrical shape having a plane on at least one surface 151 so that the wafer 190 may be positioned thereon, and plate 150 may be positioned at the bottom of the chamber 110. Alternatively, the plate 150 may have any shape which allows the wafer to contact at least one side of the plate. In addition, a pin hole 155, which may be penetrable, may be provided within the plate 150 so that the wafer support pin 170 for supporting the wafer 190 may be inserted through the pin hole 155. Thus, the wafer support pin 170 may be assembled so that the plate 150 may be penetrable by the pin hole 155.

A temperature controlling unit 160 that regulates the temperature of the plate 150 may be provided within the plate 150. When the temperature controlling unit 160 is operated, the plate 150 may reach and maintain a temperature set by the temperature controlling unit 160. Thus, the temperature of the wafer 190 disposed near the plate 150 or positioned in direct contact with a surface 151 of the plate 150 may be regulated by thermal conduction of the plate 150. The plate 150 may be formed of a material having high thermal conduction efficiency, for example, a thermally conductive material. The plate 150 may be a cooling plate for regulating the temperature of the wafer from a higher temperature to a lower temperature; or the plate 150 may be a heating plate for regulating the temperature of the wafer from a lower temperature to a higher temperature. In alternative embodiments, the plate may be formed of any conductive material as would be appreciated by one of ordinary skill in the art.

The temperature controlling unit 160, within the plate 150, may be provided in various forms. For example, the temperature controlling unit 160 may be in the form of a water flow pipe in which water flows (not shown), a gas flow pipe in which a gas flows (not shown), and a thermally conductive device adopting the principle that one side may be maintained a higher temperature than the other side where a voltage is applied. The temperature controlling unit 160 may be a thermally conductive device formed by layering n-type and p-type semiconductors where an insulator may be between.

In addition, the temperature controlling unit 160 provided in the plate 150 may be positioned near the surface 151 of the plate 150. In an example embodiment, the wafer 190 positioned near the plate 150 may be in close proximity to the temperature controlling unit 160 positioned near the surface 151 of the plate 150. Thus, the wafer 190 may reach and maintain a desired temperature by the temperature controlling unit 160 with minimal time delay.

The wafer support pin 170 may penetrate the plate 150 through the pin hole 155 formed in the plate 150 and may be capable of movement using the positioning assembly 130. Thus, the wafer support pin 170 may be adjusted using the positioning assembly 130 while the wafer 190 is supported so that the wafer 190 may move in the direction of the wafer support pin 170. In an example embodiment, the wafer support pin 170, as shown in the drawings, may include three pins. In an example embodiment, the three pins may be disposed so that they are spaced apart by approximately 120-degrees. In another example embodiment, the wafer 190 supported by the wafer support pin 170 may be stable.

The wafer support pin 170 may be adjusted so that a part of the wafer support pin 170 protrudes through the surface 151 of the plate 150 when the wafer 190 is loaded. The wafer 190, which may be loaded from outside by a wafer transfer assembly (not shown) or similar device, may be positioned on the surface 171 of the wafer support pin 170 protruding through the surface 151 of the plate 150. That is, the wafer 190 may be loaded to the wafer support pin 170.

The positioning assembly 130 may adjust the wafer support pin 170, on which the wafer 190 may be loaded, into the interior of the plate 150, or toward any surface of the plate 150 other than the surface 151 near the wafer 190. Thus, the wafer 190 seated on the surface 171 of the wafer support pin 170 may be positioned near the plate 150 as the wafer support pin 170 penetrates the plate 150, so that it may be in close proximity to the surface 151 of the plate 150.

The positioning assembly 130 may be a pin elevator, as shown in FIGS. 1-3, which may include a driving motor 137, a screw unit 138, a coupling 136, a support member 139 and/or a controller 131. The screw unit 138, coupled to the driving motor 137 and the wafer support pin 170, may adjust the wafer support pin 170 by a distance correspond to a rotation of the driving motor 137. The coupling 136 may couple the driving motor 137 to the screw unit 138. The controller 131, electrically connected to the driving motor 137, may control a rotation direction and a rotation angle of the driving motor 137. The support member 139 may support one side of the rotation shaft 132.

The driving motor 137 may include a stepping motor, which rotates at an angle corresponding to an input pulse value, and may be connected to the controller 131. The controller 131 may control the position of the wafer 190 by sending a pulse value to the stepping motor.

The screw unit 138 may include a rotation shaft 132, a spiral 133, a nut member 134 and a plurality of rolling elements 135, e.g., spherical or round in shape. The screw unit 138 may be a load type disposed toward the direction of movement of the wafer support pin 170, and which may be rotated while coupled to the coupling 136. Further, the screw unit 138 may have a spiral 133 on its outer circumference. The nut member 134, coupled to the rotation shaft 132 and the wafer support pin 170 may be adjusted according to a rotation of the rotation shaft 132. The plurality of rolling elements 135 may be provided between the nut member 134 and the rotation shaft 132 so that the nut member 134 may be smoothly adjusted according to the rotation of the rotation shaft 132.

Accordingly, when the stepping motor (not shown) is rotated, the rotation shaft 132 coupled to the stepping motor by the coupling 136 may be rotated in approximately the same rotation direction of the stepping motor. In addition, the nut member 134 may be adjusted by a distance according to the rotation direction of the rotation shaft 132. Thus, the nut member 134 adjusts the wafer support pin 170, coupled to the nut member 134. The wafer support pin 170 may adjust the position of the wafer 190.

A temperature regulation apparatus 200 may be realized according to another example embodiment of the present invention as shown in FIG. 5.

The positioning assembly 230 included in the temperature regulating apparatus 200 according to another example embodiment of the present invention may be a pin elevator which may include, all of the respective elements shown in positioning assembly 130, furthermore, a temperature sensor 275 for measuring a temperature of the wafer 290. In an example embodiment, the temperature sensor 275 may be located at any position where the temperature of the wafer 290 may be measured. In alternative embodiments, the temperature sensor 275 may be located near a surface 271, or extremities, of the wafer support pin 270 that may be in contact with one side of the wafer 290.

The temperature sensor 275 may be coupled to a controller 231. Temperature data from the wafer 290, measured by the temperature sensor 275, may be input to the controller 231. Thus, the controller 231 may control the position of the wafer support pin 270 and the wafer 290 according to the temperature detected by the temperature sensor 275.

A temperature regulation apparatus 300 may be realized according to another example embodiment of the present invention as shown in FIG. 6.

The positioning assembly 330 included in the temperature regulating apparatus 300 according to another example embodiment of the present invention may be a pin elevator which may include, as shown in FIG. 6, a driving motor 337, a driving pulley 345, a coupling 336, a follower pulley 343, a timing belt 342, a joining member 344 and/or a controller 331. The driving pulley 345 may be coupled to the driving motor 337. The coupling 336 may couple the driving motor 337 to the driving pulley 345. The follower pulley 343 may move in substantially the same direction of movement as the wafer support pin 370. The timing belt 342, coupled to the pulleys 343 and 345, may rotate as the driving motor 337 rotates. The joining member 344 may be coupled to the timing belt 342 and the wafer support pin 370. The controller 331, electrically connected to the driving motor 337, may control a rotation direction and a rotation angle of the driving motor 337.

The driving motor 337 and the timing belt 342 may rotate when the driving pulley 345 and the follower pulley 343, coupled to the driving motor 337, rotate. Thus, the wafer support pin 370, coupled to the timing belt 342 may be adjusted according to the rotation of the timing belt 342. Further, the position of the wafer 390 may be adjusted according to the movement of the wafer support pin 370.

A temperature regulation apparatus 400 may be realized according to another example embodiment of the present invention as shown in FIG. 7.

The positioning assembly 430 included in the temperature regulating apparatus 400 according to another example embodiment of the present invention may be a pin elevator which may include, as shown in FIG. 7, a driving motor 437, a driving gear 425, a follower gear 423, a chain 422, a joining member 424 and/or a controller 431. The driving gear 425 coupled to the driving motor 437. The follower gear 423 may move in substantially the same direction of movement as the wafer support pin 470. The chain 422, coupled to the gears 423 and 425, may rotate the driving motor 437 rotates. The joining member 424 may be coupled to the chain 422 and the wafer support pin 470. The controller 431, electrically connected to the driving motor 437, may control a rotation direction and a rotation angle of the driving motor 437.

In another example embodiment, when the driving motor 437 is rotated, the chain 422 may be rotated by as the driving gear 425 and the follower gear 423, rotate. In another example embodiment, the wafer support pin 470, coupled to the chain 422, may be adjusted according to the rotation of the chain 422. Thus, the position of the wafer 490 may be adjusted in the direction of movement of the wafer support pin 470.

Hereinafter, a method for regulating the temperature of a wafer according to example, non-limiting embodiments of the present invention will be described in detail. For simplicity, in the description of the method for regulating the temperature according to an example embodiment of the present invention, a temperature controlling method using a screw unit, as shown in FIGS. 1-3 and 5, will be described.

The temperature of the wafer 190/290 may regulated by adjusting the wafer 190/290 relative to the plate 150/250. Specifically, the driving motor 137/237 may be rotated in a forward or reverse direction by an angle according to the input pulse value and the position of the wafer 190/290. A rotation shaft 132/232, coupled to the driving motor 137/237 by means of a coupling 136/236, may also rotate. The nut member 134/234, coupled to the rotation shaft 132/232, and the wafer support pin 170/270, coupled to the nut member 134/234, may be adjusted by a distance corresponding to the rotation of the rotation shaft 132/232. Accordingly, a part of the wafer support pin 170/270 may move through a pin hole 155/255 and may protrude from the surface 151/251 of the plate 150/250 by the height (S10).

When the wafer support pin 170/270 protrudes from the surface 151/251 of the plate 150/250, a wafer transfer assembly (not shown), or similar device, may load the wafer 190/290 on the surface 171/271 of the wafer support pin 170/270 protruding from the surface 151/251 of the plate 150/250 (S20).

The wafer 190/290, loaded on the surface 171/271 of the wafer support pin 170/270, may be adjusted to a position substantially adjacent to the plate 150/250 when the controllers 131/231 of the positioning assembly 130/230 transfers a pulse value to the driving motor 137/237.

Accordingly, the driving motor 137/237 may rotate in the reverse direction, e.g., forward and backward and at an angle. The rotation shaft 132/232, coupled to the driving motor 137/237 by means of the coupling 136/236, may also rotate in substantially the same direction as the driving motor 137/237. Accordingly, the nut member 134/234, coupled to the rotation shaft 132/232, and the wafer support pin 170/270, which may be coupled to the nut member 134/234, may be adjusted by a distance corresponding to the rotation of the rotation shaft 132/232. Here, the wafer 190/290 may be disposed at a position that may be determined by the controllers 131/231, namely, position adjacent to the plate 150/250. In addition, initially the position of the wafer 190/290, substantially adjacent to the plate 150/250, may be spaced from the surface 151/251 of the plate 150/250 by a distance L, as shown in FIG. 2. The distance, L, may be scaled according to the other operation parameter (e.g., the size of the wafer 190/290, temperature controlling unit 160/260, and temperature regulation apparatus 100/200. In a case where the temperature controlling unit 160/260 may be included in the chamber 110/220, the position that the wafer 190/290 may be initially adjusted substantially adjacent to the temperature controlling unit 160/260. Further, the wafer 190/290 that may be spaced approximately 1 to 10 mm from the surface of the temperature controlling unit 160/260.

The temperature of the adjusted wafer 190/290 may be regulated for a preferred amount of time or until a desired temperature is reached (S30). For example, the adjusted wafer 190/290 may remain in a position for approximately 3 to 10 seconds and at a temperature of approximately 90 to 120° C. The temperature regulation method may be performed by heat radiation of the plate 150/250 regulated by the temperature controlling unit 160/260 or heat radiation of the temperature controlling unit 160/260.

The controllers 131/231 of the positioning assembly 130/230 may transfer a pulse value to the driving motor 137/237 so that the adjusted wafer 190/290 may be in substantially direct, or direct, contact with the plate 150/250.

Specifically, the driving motor 137/237 may rotate further in the usual rotation direction and the rotation shaft 132/232, coupled to the driving motor 137/237 by means of the coupling 136/236, may also further rotated in the same direction of the driving motor 137/237 by a corresponding angle. Accordingly, the nut member 134/234, coupled to the rotation shaft 132/232, and the wafer support pin 170/270, which may be coupled to the nut member 134/234, may be further adjusted according to the rotation of the rotation shaft 132/232. Accordingly, the wafer 190/290 may be adjusted to a position determined by the controllers 131/231, namely, a position that may be in substantially direct or direct contact with the surface 151/251 of the plate 150/250. Here, the wafer support pin 170/270 may be disposed in the interior of the plate 150/250 or near a surface of the plate 150/250 other than the surface 151/251 nearest to the wafer 190/290.

Temperature of the wafer 190/290 may be regulated for a preferred amount of time or until a desired temperature is reached (S40). For example, the wafer 190/290 may be cooled to temperatures of 83° C., 23° C., 3° C., etc. In addition, since the wafer 190/290 may be in substantially direct, or direct, contact with the plate 150/250, the temperature controlling method may be performed by conduction and radiation of the plate 150/250 regulated by the temperature controlling unit 160/260 or conduction and radiation of the temperature controlling unit 160/260. Accordingly, temperature of the wafer 190/290 that is in substantially direct, or direct, contact with the plate 150/260 may be adjusted according to the combination heat conduction method.

When the wafer 190/290 is cooled to a desirable temperature, the controllers 131/231 of the pin elevator may transfer an input pulse value to the driving motor 137/237 so that the wafer support pin 170/270 may position wafer 190/290 away from the plate 150/250.

As a result, the driving motor 137/237 may rotate in a forward or reverse direction that corresponds to the input pulse value. The rotation shaft 132/232, coupled to the driving motor 137/237 by means of the coupling 136/236, may be rotated. In addition, when the rotation shaft 132/232 is rotated, the nut member 134/234 coupled to the rotation shaft 132/232 and the wafer support pin 170/270 coupled to the nut member 134/234, may be adjusted by a distance corresponding to the rotation of the rotation shaft 132/232. Therefore, a part of the wafer support pin 170/270 may penetrate through the pin hole 155/255 and protrude from the surface 151/251 of the plate 150/250, so that the wafer 190/290 that is in substantially direct, or direct, contact with the plate 150/250 may be positioned away from the cooling plate 150/250. Thus, a wafer transfer assembly, or similar device, may unload the wafer 190/290 from the wafer support pin 170/270 to the outside (S50).

Accordingly, in a method and apparatus for adjusting the temperature of a wafer according to the example embodiments of the present invention, instead of drastically changing the temperature, for instance by cooling a baked wafer by placing the wafer in contact to a lower temperature plate, the temperature of a wafer may be regulated by performing indirect and direct temperature regulating operations. Therefore, fracturing a wafer according to conventional methods and apparatuses may be reduced or prevented.

While the example embodiments of the present invention have been described in terms of cooling (e.g., higher temperature to lower temperature), it should be appreciated by one of ordinary skill that given the materials used to create the circuit pattern, heating (e.g., lower temperature to higher temperature) may be performed.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. An apparatus for regulating a temperature of a wafer comprising:
a chamber;
a temperature controlling unit provided within the chamber and regulating the temperature of the wafer;
a wafer support pin for adjusting a position of the wafer with respect to the temperature controlling unit; and
a positioning assembly for adjusting the wafer support pin by which the position of the wafer is controlled.

2. The apparatus according to claim 1, wherein the temperature controlling unit is a cooling unit.

3. The apparatus according to claim 2, wherein the cooling unit includes a thermoelectric module.

4. The apparatus according to claim 1, wherein the chamber comprises a plate on which the wafer is positioned and the temperature controlling unit is provided within the plate.

5. The apparatus according to claim 4, wherein the plate is a cooling plate formed of a thermally conductive material.

6. The apparatus according to claim 1, wherein the positioning assembly is a pin elevator comprising:
a driving motor;
a screw unit, coupled to the driving motor and the wafer support pin, for adjusting the position of the wafer support pin by rotating the driving motor; and
a controller, electrically connected to the driving motor, for controlling a rotation direction and a rotation angle of the driving motor.

7. The apparatus according to claim 6, wherein the driving motor includes a stepping motor rotated at an angle corresponding to an input pulse value.

8. The apparatus according to claim 6, wherein the pin elevator further comprises a temperature sensor for measuring the temperature of the wafer, and the controller controls the rotation direction and the angle of the driving motor as the wafer temperature is detected by the temperature sensor.

9. The apparatus according to claim 8, wherein the temperature sensor is provided with the wafer support pin.

10. The apparatus according to claim 9, wherein the temperature sensor is provided near a portion of the wafer support pin in contact with the wafer.

11. The apparatus according to claim 6, wherein the screw unit further comprises:
a rotation shaft disposed substantially parallel to a moving direction of the wafer support pin; and
a nut member coupled to the rotation shaft being adjusted as the rotation shaft rotates, wherein the wafer support pin is coupled to the nut member.

12. The apparatus according to claim 1, wherein the positioning assembly is a pin elevator comprising:
a driving motor;
a driving pulley coupled to the driving motor;
a follower pulley oriented in a direction substantially the same as a direction of movement of the wafer support pin;
a timing belt, coupled to the driving pulley and follower pulley, being rotated as the driving motor is rotated;
a joining member, coupled to the timing belt and the wafer support pin; and
a controller, electrically connected to the driving motor, for controlling a rotation direction and an angle of the driving motor.

13. The apparatus according to claim 1, wherein the positioning assembly is a pin elevator comprising:
a driving motor;
a driving gear coupled to the driving motor;
a follower gear oriented in a direction substantially the same as a direction of movement of the wafer support pin;
a chain, coupled to the driving gear and follower gear, for being rotated as the driving motor is rotated;
a joining member coupled to the chain and the wafer support pin; and
a controller, electrically connected to the driving motor, for controlling a rotation direction and an angle of the driving motor.

14. A method for regulating a temperature of a wafer comprising:
adjusting a positioning assembly relative to a surface of a plate;
loading the wafer on the positioning assembly;
regulating the temperature of the wafer by adjusting the wafer a distance from the surface of the plate; and
subsequently regulating the temperature of the wafer by adjusting the wafer to be in contact with the surface of the plate.

15. The method according to claim 14, wherein adjusting the positioning assembly includes adjusting a pin elevator.

16. The method according to claim 14, wherein regulating the temperature of the wafer includes cooling the wafer.

17. The method according to claim 14, wherein regulating the temperature of the wafer includes regulating the temperature of the wafer by thermal radiation when the wafer is adjusted the distance from the surface of the plate.

18. The method according to claim 17, wherein the wafer is approximately 1 to 10 mm from the surface of the plate.

19. The method according to claim 14, wherein the temperature of the wafer is regulated for approximately 3 to 10 seconds.

20. The method according to claim 14, wherein subsequently regulating the temperature of the wafer includes regulating the temperature of the wafer by thermal conduction and thermal radiation when the wafer is adjusted to be in contact with the surface of the plate.

21. The method according to claim 14, further comprising measuring the temperature of the wafer using a temperature sensor.

22. The method according to claim 21, wherein subsequently regulating the temperature of the wafer, adjusted to be in contact with the surface of the plate, is performed after the temperature of the wafer, regulated by adjusting the wafer the distance from the surface of the plate, is approximately 90 to 120° C.

23. The method according to claim 21, further comprising positioning the temperature sensor near a portion of the positioning assembly contacting the wafer.

24. An apparatus for regulating the temperature of a wafer according to the method of claim 14.
